(19) United States
(12) Patent Application Publication
(10) Pub. No.: US 2023/0017908 A1
(43) Pub. Date: Jan. 19, 2023

(54) SEMICONDUCTOR PACKAGE

(71) Applicant: SAMSUNG ELECTRONICS CO., LTD., Suwon-si (KR)

(72) Inventor: Jooyoung OH, Suwon-si (KR)

(21) Appl. No.: 17/708,470

(22) Filed: Mar. 30, 2022

(30) Foreign Application Priority Data
Jul. 9, 2021 (KR) 10-2021-0090138

(51) Int. Cl. H01L 23/00; H01L 23/495; H01L 23/538; H01L 23/522; H01L 23/48

(52) U.S. Cl. CPC H01L 24/48; H01L 24/16; H01L 23/49582; H01L 23/5384; H01L 23/5226; H01L 23/481; H01L 2924/15311; H01L 2224/48227; H01L 2224/48247; H01L 2224/73265; H01L 2224/48091

(57) ABSTRACT

A semiconductor package includes: a substrate structure having a first surface and an opposite second surface; a semiconductor chip on the first surface; and a connection bump on the second surface. The substrate structure includes: interconnection patterns disposed at different levels relative to the second surface; connection vias connecting the interconnection patterns; and a passivation layer covering a portion of the interconnection patterns and having an opening. The interconnection patterns include a first pattern and a second pattern, wherein the first pattern and the second pattern are adjacent to the second surface, and wherein a side surface of the first pattern faces a side surface of the second pattern. The second pattern includes a pad pattern and a metal layer in contact with the pad pattern and the connection bump. The first pattern has a first thickness and the second pattern has a pad thickness that is greater than the first thickness.

### CROSS-REFERENCE TO RELATED APPLICATION(S)

This application claims benefit of priority to Korean Patent Application No. 10-2021-0090138 filed on Jul. 9, 2021 in the Korean Intellectual Property Office, the disclosure of which is incorporated herein by reference in its entirety.

### BACKGROUND

The present disclosure relates to a semiconductor package.

A semiconductor package may be mounted on a substrate (for example, a mainboard, or the like) through connection bumps such as solder balls, or the like. Reliability of a semiconductor package may be affected by a state of connection between the connection bumps and the semiconductor package. To enhance reliability of semiconductor packages, it is desirable to reduce or prevent cracking from occurring in pad patterns, connection bumps, etc.

### SUMMARY

Example embodiments provide a semiconductor package having improved electrical characteristics and reliability.

According to an example embodiment, a semiconductor package includes: a substrate structure comprises a first surface and an opposite second surface; a semiconductor chip on the first surface of the substrate structure; and a connection bump on the second surface. The substrate structure includes: interconnection patterns at different levels relative to the second surface; connection vias electrically connecting the interconnection patterns; and a passivation layer covering a portion of the interconnection patterns and having an opening exposing a portion of the second surface. The interconnection patterns comprise a first pattern and a second pattern, wherein the first pattern and the second pattern are adjacent to the second surface, and wherein a side surface of the first pattern faces a side surface of the second pattern. The first pattern is spaced apart from the opening. The second pattern comprises a pad pattern and a metal layer, wherein the metal layer is between the pad pattern and the connection bump and is in contact with the pad pattern and the connection bump. The opening of the passivation layer is configured such that the passivation layer does not cover at least a portion of the pad pattern. Each of the pad pattern and the metal layer comprises copper (Cu). The first pattern has a first thickness between an upper surface and a lower surface of the first pattern in a direction perpendicular to the first surface. The second pattern has a pad thickness between an upper surface and a lower surface of the second pattern in the direction. The pad thickness is greater than the first thickness.

According to an example embodiment, a semiconductor package comprises: a substrate structure comprising interconnection patterns and connection vias electrically connected to each other, insulating layers covering the interconnection patterns and the connection vias, and a passivation layer having an opening; and a semiconductor chip on the substrate structure and electrically connected to the substrate structure. The substrate structure comprises a first surface and an opposite second surface, wherein the semiconductor chip is on the first surface. The interconnection patterns comprise a pad structure that comprises a pad pattern and a metal layer in contact with a lower surface of the pad pattern. The pad pattern and the metal layer comprise the same metal. The pad structure has a pad thickness between an upper surface and a lower surface of the pad structure in a direction perpendicular to the first surface. One of the interconnection patterns comprises a side surface facing a side surface of the pad structure, wherein the one of the interconnection patterns has a first thickness between an upper surface and a lower surface thereof in the direction. The pad thickness is greater than the first thickness.

According to an example embodiment, a semiconductor package comprises: a substrate structure comprising interconnection patterns and connection vias electrically connected to each other, insulating layers covering the interconnection patterns and the connection vias, a passivation layer having an opening, and a metal layer in at least one region of the opening; a first semiconductor chip on the substrate structure and electrically connected to the interconnection patterns; and a first connection bump below the substrate structure and electrically connected to the interconnection patterns. The interconnection patterns comprise a pad structure. The pad structure comprises a pad pattern comprising copper (Cu) and a metal layer comprising Cu. An upper surface of the metal layer is in contact with the pad pattern, a lower surface of the metal layer is in contact with the first connection bump, and a side surface of the metal layer is in contact with the passivation layer at the opening. A width of the metal layer is smaller than a maximum width of the opening. The lower surface of the metal layer is at a level lower than an upper surface of the passivation layer.

### BRIEF DESCRIPTION OF DRAWINGS

The above and other aspects, features, and advantages of the present disclosure will be more clearly understood from the following detailed description, taken in conjunction with the accompanying drawings.

FIG. 1 is a cross-sectional view of a semiconductor package according to example embodiments.

FIGS. 2A and 2B are partially enlarged cross-sectional views of a semiconductor package according to example embodiments.

FIGS. 3 to 5 are partially enlarged cross-sectional views of a semiconductor package according to example embodiments.

FIG. 6 is a cross-sectional view of a semiconductor package according to example embodiments.

FIG. 7 is a partially enlarged cross-sectional view of a semiconductor package according to example embodiments.

FIGS. 8 to 11 are cross-sectional views of semiconductor packages according to example embodiments, respectively.

FIGS. 12A to 12D are schematic cross-sectional views illustrating a method of manufacturing the semiconductor package of FIG. 1.

### DETAILED DESCRIPTION

Hereinafter, example embodiments will be described with reference to the accompanying drawings.

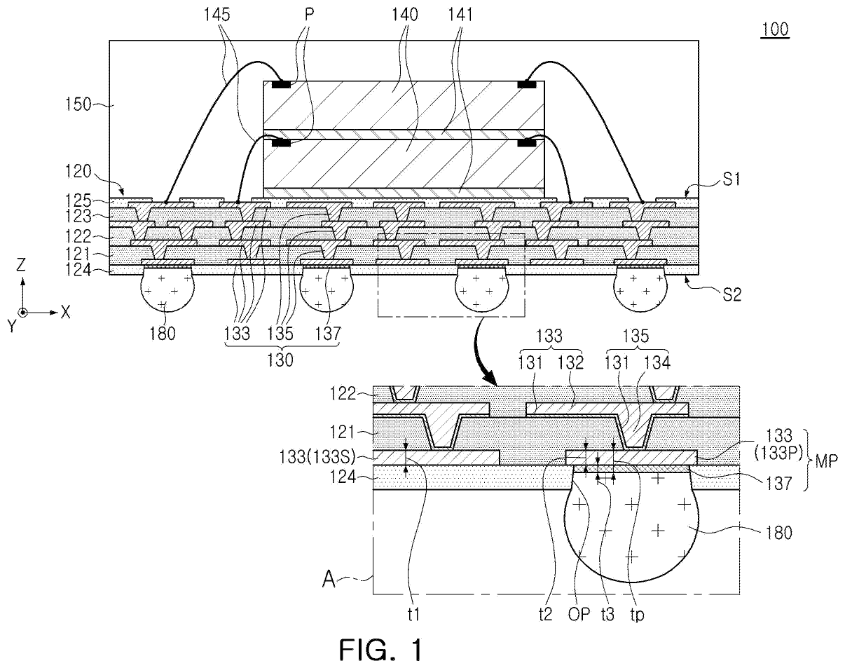

FIG. 1 is a cross-sectional view of a semiconductor package according to example embodiments. In FIG. 1, region “A” including a pad structure MP is illustrated as enlarged.

Referring to FIG. 1, a semiconductor package 100 may include a substrate structure 120, a semiconductor chip 140 on the substrate structure 120, connection bumps 180 below the substrate structure 120, and a capping layer 150 encapsulating the semiconductor chip 140. The semiconductor package 100 may further include a bonding wire 145.

The substrate structure 120 may include insulating layers 121, 122, and 123, passivation layers 124 and 125, and an interconnection structure 130. The interconnection structure 130 may include interconnection patterns 133, connection vias 135, and metal layers 137. The substrate structure 120 may be a support substrate on which the semiconductor chip 140 is mounted. The substrate structure 120 may have a first surface S1, on which the semiconductor chip 140 is disposed, and a second surface S2, opposing the first surface S1, on which the connection bump 180 is disposed. The first and second surfaces S1 and S2 may be disposed on sides opposing each other.

The insulating layers 121, 122, and 123 may include a plurality of insulating layers 121, 122, and 123 stacked in a vertical direction Z, for example, a first insulating layer 121, a second insulating layer 122, and a third insulating layer 123, as illustrated in FIG. 1. The insulating layers 121, 122, and 123 may cover interconnection patterns 133 and connection vias 135, as illustrated in FIG. 1. The insulating layers 121, 122, and 123 may include an insulating resin. Examples of the insulating resin may include a thermosetting resin such as an epoxy resin, a thermoplastic resin such as polyimide, or an insulating material in which these resins are impregnated in a core material such as an inorganic filler and/or glass fibers (glass fiber, glass cloth, glass fabric), for example, prepreg, Ajinomoto Build-up Film (ABF), FR-4, Bismaleimide Triazine (BT), and the like. The insulating layers 121, 122, and 123 may include a photosensitive resin such as a photoimageable dielectric (PID) resin. In this case, the insulating layers 121, 122, and 123 may be formed to be thinner, and fine interconnection patterns 133 and connection vias 135 may be formed. Depending on a process, boundaries between the insulating layers 121, 122, and 123 having different levels may not be apparent.

The passivation layers 124 and 125 may be provided as layers for protecting the semiconductor package from external physical and chemical damage. The passivation layers 124 and 125 may protect the substrate structure 120. The first passivation layer 124 may be disposed in a lower region of the substrate structure 120 to cover, for example, a lower surface of the first insulating layer 121. The second passivation layer 125 may be disposed in an upper region of the substrate structure 120 to cover, for example, an upper surface of the third insulating layer 123. The passivation layers 124 and 125 may include an insulating resin and an inorganic filler, but may not include a glass fiber. For example, the passivation layers 124 and 125 may include ABF, but example embodiments are not limited thereto. The passivation layers 124 and 125 may include a photoimageable dielectric material (PID) or an insulating polymer, for example, photosensitive polyimide (PSPI). The passivation layers 124 and 125 may have openings, respectively exposing a lower surface and an upper surface of the substrate structure 120. The opening OP of the first passivation layer 124 may expose the second surface S2 of the substrate structure 120, and the pad pattern 133P may be exposed through the opening OP. A metal layer 137 may be disposed in at least one region of the opening OP of the first passivation layer 124. A portion of the interconnection patterns 133 may be exposed through the opening of the second passivation layer 125 to be connected to the bonding wire 145.

The interconnection patterns 133 may be disposed on or in the insulating layers 121, 122, and 123. The interconnection patterns 133 may include a plurality of interconnection patterns 133 disposed on different height levels from the second surface S2 of the substrate structure 120. The interconnection patterns 133 may be electrically connected to each other. The interconnection patterns 133 may be electrically connected to the semiconductor chip 140 and the connection bump 180, but example embodiments are not limited thereto. The interconnection patterns 133 may redistribute a connection pad P of the semiconductor chip 140.

The interconnection patterns 133 may include a first pattern 133S and a second pattern MP spaced apart from each other. The second pattern MP may be referred to as a “pad structure MP.” The second pattern 133P may include a pad pattern 133P and a metal layer 137. The first pattern 133S and the pad pattern 133P may be disposed to be adjacent to the second surface S2 of the substrate structure 120, and may be disposed to be farther from the first surface S1 of the substrate structure 120 than interconnection patterns 133 disposed on a height level different from a height level of the first and second patterns 133S and 133P. The first pattern 133S may be one interconnection pattern 133 having a side surface facing the side surface of the pad pattern 133P, among the interconnection patterns 133. One surface of the first pattern 133S may be completely covered with the first passivation layer 124. At least a portion of the pad pattern 133P may be exposed to the opening OP. The first pattern 133S may be spaced apart from the pad pattern 133P, the opening OP, and the connection bump 180. A side surface of the first pattern 133S and a side surface of the pad pattern 133P may face each other, as illustrated in FIG. 1.

The pad pattern 133P may have a solder mask defined (SMD) structure. For example, a width of the opening OP of the first passivation layer 124 may be smaller than a width of the pad pattern 133P. Accordingly, a portion of a lower surface of the pad pattern 133P may be exposed to the opening OP and another portion thereof may be covered with the first passivation layer 124.

The first pattern 133S may have a first thickness t1 between a lower surface and an upper surface of the first pattern 133S in a vertical direction Z, perpendicular to the first surface S1 of the substrate structure 120 or the lower surface of the semiconductor chip 140, and the pad pattern 133P may have a second thickness t2 between an upper surface and a lower surface of the pad pattern 133P in the vertical direction Z, as illustrated in FIG. 1. The first thickness t1 and the second thickness t2 may be substantially the same. As used herein, the term “substantially the same” refers to the same or the case in which there is a difference within a range of deviation occurring in a manufacturing process. Even when the term “substantially” is omitted, it may be interpreted as the same meaning. The upper surface of the first pattern 133S and the upper surface of the pad pattern 133P may be disposed at the same level, as illustrated in FIG. 1. In an example embodiment, the second thickness t2 may be equal to about twice or more of the third thickness t3 of the metal layer 137, as will be described below. In an example embodiment, the second thickness t2 may be about 10 μm or more, for example, about 10 μm or more to about 20 μm or less.

The interconnection patterns 133 may include a barrier layer 131 and an interconnection conductive layer 132, as illustrated in FIG. 1. The barrier layer 131 may include at least one of titanium (Ti), tantalum (Ta), cobalt (Co), titanium nitride (TiN), and tantalum nitride (TaN). The interconnection conductive layer 132 may include a metallic material such as copper (Cu), aluminum (Al), silver (Ag), tin (Sn), gold (Au), nickel (Ni), lead (Pb), or titanium (Ti), or alloys thereof. The interconnection patterns 133 may perform various functions depending on a design thereof. For example, the interconnection patterns 133 may include a ground (GND) pattern, a power (PWR) pattern, and a signal (S) pattern. The signal (S) pattern may include various signals, other than the ground (GND) pattern, the power (PWR) pattern, and the like, such as a data signal.

The connection vias 135 may penetrate through the insulating layers 121, 122, and 123 to interconnect the plurality of interconnection patterns 133. For example, the connection via 135 may vertically, electrically connect the plurality of interconnection patterns 133 disposed at different levels. The connection via 135 may include a signal via, a ground via, and a power via. The connection vias 135 may include a barrier layer 131 and an interconnection via layer 134. The barrier layer 131 may extend along a lower surface of the interconnection patterns 133 and a lower surface and side surfaces of the connection vias 135. The interconnection via layer 134 may include a metallic material such as copper (Cu), aluminum (Al), silver (Ag), tin (Sn), gold (Au), nickel (Ni), lead (Pb), titanium (Ti), or alloys thereof. Each of the connection vias 135 may be a filled via completely filled with a metal material, or a conformal via formed along a wall surface of a via hole.

The metal layers 137 may be disposed in one region of the opening OP of the first passivation layer 124 and may be in contact with the pad pattern 133P. For example, the metal layers 137 may be in contact with a portion of the lower surface of the pad pattern 133P exposed to the opening OP of the first passivation layer 124. The metal layers 137 may be in contact with a sidewall of the opening OP of the first passivation layer 124. The metal layers 137 may be in contact with the connection bumps 180, respectively. Each of the metal layers 137 may be disposed between the pad pattern 133P and the connection bump 180. The lower surface of the metal layers 137 may be disposed at a level lower than a level of the upper surface of the first passivation layer 124 and the lower surface of the first pattern 133S, as illustrated in FIG. 1. The metal layers 137 have a width smaller than a width of the pad pattern 133P, as illustrated in FIG. 1. The width of the metal layer 137 may be narrower than a maximum width of the opening OP. The metal layers 137 may include a metallic material such as copper (Cu), aluminum (Al), silver (Ag), tin (Sn), gold (Au), nickel (Ni), lead (Pb), titanium (Ti), or alloys thereof.

The metal layers 137 may have a third thickness t3 between an upper surface and a lower surface of the metal layers 137 in the vertical direction Z. The third thickness t3 may be smaller than the second thickness t2, but example embodiments are not limited thereto. The sum of the second thickness t2 and the third thickness t3 may be thicker than the first thickness t1. The metal layers 137 may be formed as, for example, a plating layer including copper (Cu) on a surface of the pad pattern 133P to increase the thickness of the pad structure MP connected to the connection bump 180. As an example, the third thickness t3 may be about 5 μm or more, for example, about 5 μm or more to about 15 μm or less.

In an exemplary embodiment, the metal layers 137 may include the same metal material as the pad pattern 133P. For example, the metal layers 137 and the pad pattern 133P may each include copper (Cu) and may constitute the pad structure MP. The pad structure MP may be exposed to the opening OP of the first passivation layer 124 and may be in contact with the connection bump 180. The pad structure MP may have a side surface facing the first pattern 133S. The pad structure MP may have a pad thickness tp in the vertical direction Z, and the pad thickness tp may be the same as the sum of the second thickness t2 and the third thickness t3. A difference between the pad thickness tp and the first thickness t1 may be about 5 μm or more, for example, about 5 μm or more to about 15 μm or less.

As the pad pattern 133P becomes finer, the pad pattern 133P may be decreased in thickness to be vulnerable to pattern cracking. During the process in which a portion of an insulating layer covering the pad pattern 133P is etched to connect the connection bump 180, the pad pattern 133P may be recessed and thinned to be more vulnerable to the pattern cracking. For example, occurrence of the pattern cracking may cause thermal cycle (TC) reliability in board-level reliability (BLR) to be significantly deteriorated. The TC reliability is a result of testing whether the reliability is maintained up to a predetermined number of cycles by periodically increasing and decreasing a temperature on a board level. According to an example embodiment, since metal layers 137 are formed by additionally performing a plating process on the pad pattern 133P exposed to the opening OP, a thickness of the pad structure MP may be increased and the pattern cracking may be prevented from occurring. Accordingly, the TC reliability may be improved to increase lifespan, and electrical characteristics and reliability of the semiconductor package may be improved.

In a comparative example, in the absence of the metal layer 137, when the second thickness t2 of the pad pattern 133P was about 15 μm or less, cracking easily occurred in the pad pattern 133P during the TC test to decrease the lifespan thereof. According to an example embodiment, even when the second thickness t2 is about 15 μm or less or a recessed portion is formed to have a thickness of about 15 μm or less in the pad pattern 133P by an etching process, the metal layer 137 may be formed to have a third thickness t3 of about 5 μm or more. Thus, patterning cracking may be prevented from occurring when a thickness tp of a final pad of the pad structure MP is decreased to about 15 μm or less.

When the substrate structure 120 is mounted on a board such as a module substrate, most of a finish layer of the board may be a pad pattern including copper (Cu) and an organic solderability preservative (OSP). When a finish layer of the substrate structure 120 is formed of nickel/gold (Ni/Au), drop test characteristics may be significantly deteriorated during a BLR test. According to an example embodiment, since the substrate structure 120 and the board include the same finish layer of a combination of copper (Cu) and OSP, drop test characteristics may be improved.

The semiconductor chip 140 may be disposed on the upper surface of the substrate structure 120 and may include a connection pad P electrically connected to the interconnection patterns 133 of the substrate structure 120. For example, the semiconductor chip 140 may be disposed such that a surface, on which the connection pad P is not disposed, faces the substrate structure 120. The connection pad P may include, for example, a metal material such as aluminum (Al). In an example embodiment, a single semiconductor chip 140 or a plurality of semiconductor chips 140 may be stacked. Each of the semiconductor chips 140 may include an adhesive layer 141 disposed on a lower surface thereof, and the adhesive layer 141 may be bonded to the substrate structure 120. The connection pad P may be disposed on a surface opposing a surface on which the adhesive layer 141 is disposed in the semiconductor chip 140. In an example embodiment, the semiconductor chip 140 may be mounted on the substrate structure 120 in a wire bonding manner. For example, the bonding wire 145 may be connected to the connection pad P and the interconnection patterns 133 to provide an electrical connection path therebetween. Alternatively, the semiconductor chip 140 may be mounted on the substrate structure 120 in a flip-chip bonding manner.

The semiconductor chip 140 may be a logic chip or a memory chip. The logic chip may include, for example, a central processing unit (CPU), a graphics processing unit (GPU), a field programmable gate array (FPGA), a digital signal processor (DSP), an encryption processor, a microprocessor, a microcontroller, an analog-digital converter, an application-specific integrated circuit (ASIC), and the like. The memory chip may include, for example, a volatile memory device such as a dynamic random access memory (DRAM) or static RAM (SRAM), or a non-volatile memory device such as a phase change RAM (PRAM), magnetic RAM (MRAM), resistive RAM (RRAM), or a flash memory.

The capping layer 150 may be disposed on the substrate structure 120 and may cover the semiconductor chip 140 and the substrate structure 120. The capping layer 150 may include an insulating material. Examples of the insulating material may include a thermosetting resin such as epoxy resin, a thermoplastic resin such as polyimide, or prepreg, Ajinomoto Build-up Film (ABF), FR-4, Bismaleimide Triazine (BT), an epoxy molding compound (EMC), and the like, including an inorganic filler and/or glass fiber.

The connection bumps 180 may have a land, a ball, or a pin shape. The connection bumps 180 may include, for example, tin (Sn) or a tin-containing alloy (for example, Sn—Ag—Cu). The connection bumps 180 may be disposed below the substrate structure 120, for example, on the second surface S2 of the substrate structure 120, and may be electrically connected to the interconnection patterns 133. The connection bump 180 may be disposed below the pad pattern 133P to be electrically connected to the pad pattern 133P exposed through the opening OP, and may be in contact with the metal layer 137. The connection bumps 180 may physically and/or electrically connect the semiconductor package 100 to an external entity. The connection bumps 180 may include, for example, solder balls.

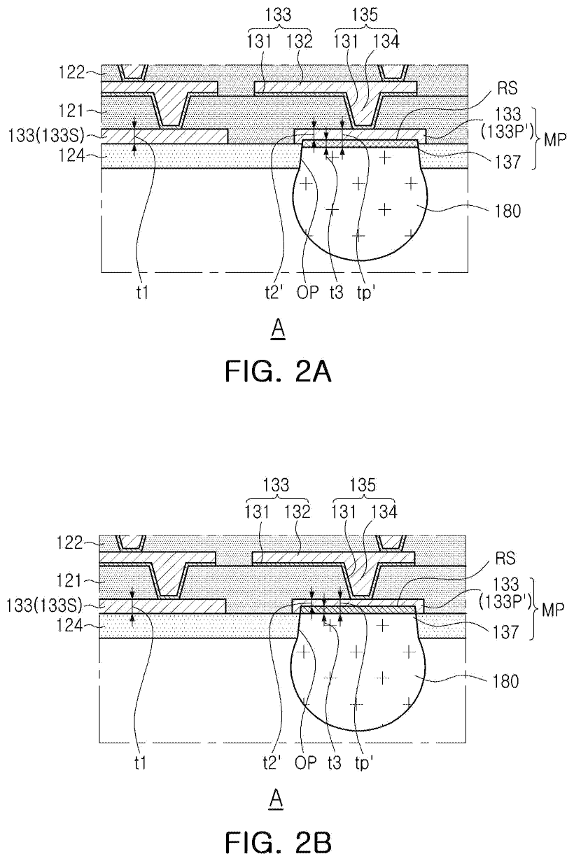

FIGS. 2A and 2B are partially enlarged cross-sectional views of a semiconductor package according to example embodiments. FIGS. 2A and 2B illustrate a region corresponding to region “A” of FIG. 1.

Referring to FIG. 2A, when the opening OP of the first passivation layer 124 is formed, a portion of a lower surface of a pad pattern 133P′ may be recessed. For example, a portion of the pad pattern 133P′ may have a region RS having a lower surface recessed such that a thickness is decreased in a vertical direction Z and, in the recessed region RS, the pad pattern 133P′ may have a second thickness t2′ smaller than a first thickness t1. The recessed region RS may be in contact with the metal layer 137. As described above, even when the pad pattern 133P′ is recessed, a thickness of the pad structure MP may be increased because the metal layer 137 is additionally formed of the same metal material as the pad pattern 133P′. Accordingly, structural stability of the pattern structure MP may be improved to prevent cracking from occurring in a pattern, resulting in improved electrical characteristics and reliability of the semiconductor package. In the present embodiment, a pad thickness tp′ may be the same as the sum of the second thickness t2′ and the third thickness t3, and a lower surface of the metal layer 137 may be disposed at a level lower than a level of a lower surface of the first pattern 133S and a lower surface of the pad pattern 133P.

Referring to FIG. 2B, when the opening OP of the first passivation layer 124 is formed, a portion of a lower surface of a pad pattern 133P′ may be recessed such that a second thickness t2′ may be greater than the first thickness t1. Even in this case, a metal layer 137 may be formed on the recessed region RS of the pad pattern 133P′ such that the pad thickness tp′ is substantially the same as the first thickness t1. Accordingly, even when the pad pattern 133P′ is recessed, the thickness of the pad structure MP may be stably secured and cracking may be prevented from occurring in the pattern, resulting in improved electrical characteristics and reliability of the semiconductor package.

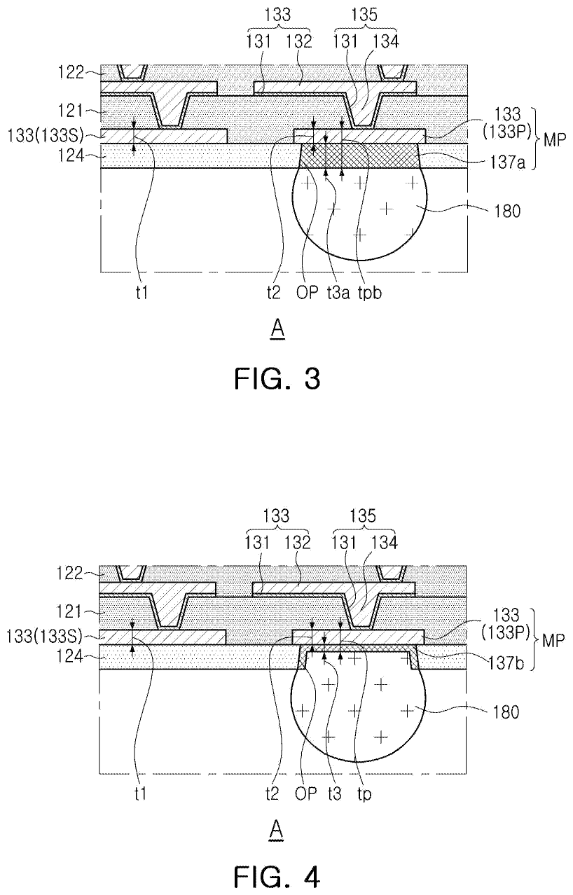

FIGS. 3 to 5 are partially enlarged cross-sectional views of a semiconductor package according to example embodiments. FIGS. 3 to 5 illustrate a region corresponding to region “A” of FIG. 1.

Referring to FIG. 3, a metal layer 137a may be disposed to fill an opening OP of a first passivation layer 124. In this case, a third thickness t3a of the metal layer 137a may be substantially the same as or greater than the second thickness t2. Even when a thickness of an interconnection patterns 133 is further decreased due to miniaturization, the metal layer 137a may be further formed on a surface of the pad pattern 133P exposed to the opening OP to provide a pad structure MP having a sufficient thickness. Accordingly, in spite of the miniaturization of the semiconductor package, cracking may be prevented from occurring in the pattern to improve electrical characteristics and reliability of the semiconductor package.

Referring to FIG. 4, a metal layer 137b may include a portion bent along a sidewall of an opening OP of a first passivation layer 124 from a portion in contact with a lower surface of a pad pattern 133P. A contact area between the connection bump 180 and the metal layer 137b may be increased and resistance may be reduced, resulting in improved electrical characteristics.

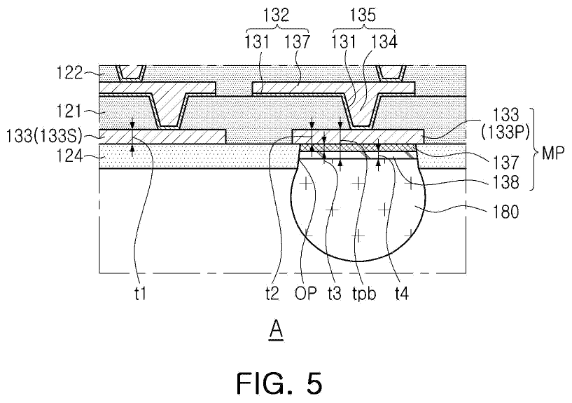

Referring to FIG. 5, the pad structure MP may include a first metal layer 137 and a second metal layer 138. The first metal layer 137 may be in contact with the pad pattern 133P, and the second metal layer 138 may be in contact with a connection bump 180. In the present embodiment, a plurality of metal layers are disposed between the pad pattern 133P and the connection bump 180, but the number of the plurality of metal layers may vary according to example embodiments. The first metal layer 137 may have a third thickness t3 in a vertical direction Z, and the second metal layer 138 may have a fourth thickness t4 in the vertical direction Z. A pad thickness tpb of a pad structure MP may be the same as the sum of the second, third, and fourth thicknesses t2, t3, and t4. The third thickness t3 and the fourth thickness t4 may be the same or different from each other. Even when a thickness of an interconnection patterns 133 is further reduced due to miniaturization, a plurality of metal layers may be formed on a surface of the pad pattern 133P exposed to the opening OP to provide a pad structure MP having a sufficient thickness. Accordingly, in spite of miniaturization of the semiconductor package, cracking may be prevented from occurring in the pattern to improve electrical characteristics and reliability of the semiconductor package.

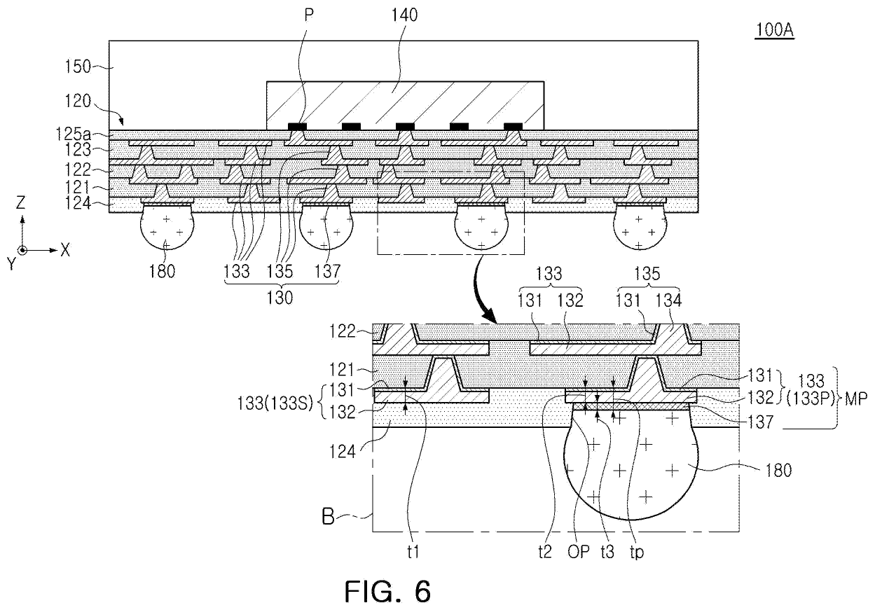

FIG. 6 is a cross-sectional view of a semiconductor package according to example embodiments. In FIG. 6, region “A” including a pad structure MP is illustrated as enlarged.

Referring to FIG. 6, in a semiconductor package 100A, a semiconductor chip 140 may be disposed such that a connection pad P faces a substrate structure 120, and connection vias 135 penetrating through a fourth insulating layer 125a of a substrate structure 120 may be directly connected to a connection pad P. Unlike the above-described embodiments, the connection vias 135 may have inclined side surfaces narrowed in a direction toward an upper surface of the substrate structure 120, as illustrated in FIG. 6. The pad pattern 133P may include a barrier layer 131 and a conductive wire layer 132, and a metal layer 137 may be disposed to be in contact with a lower surface of the pad pattern 133P exposed to an opening of a passivation layer 124. The passivation layer 124 may be in contact with a side surface of the pad pattern 133P and a side surface of the first pattern 133S.

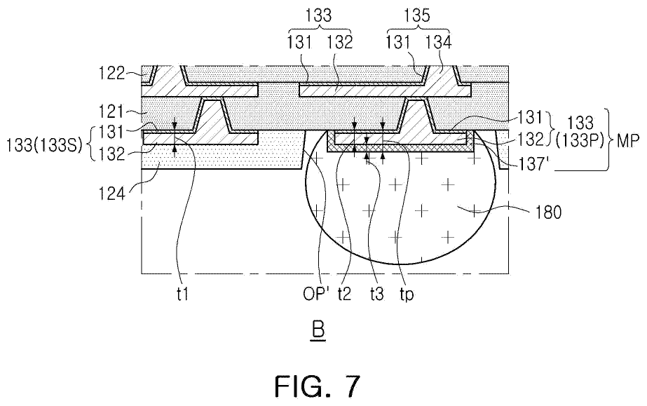

FIG. 7 is a cross-sectional view of a semiconductor package according to example embodiments. In FIG. 7, a region corresponding to region “B” of FIG. 6 is illustrated.

Referring to FIG. 7, a pad pattern 133P may have a non-solder mask defined (NSMD) structure. For example, a width of an opening OP of a passivation layer 124 may be greater than a width of a pad pattern 133P, and side surfaces of the pad pattern 133P and a metal layer 137′ may be exposed to the opening OP. The metal layer 137′ may be disposed to surround a lower surface and side surfaces of the pad pattern 133P, and a connection bump 180 may be in contact with a lower surface and side surfaces of the metal layer 137′.

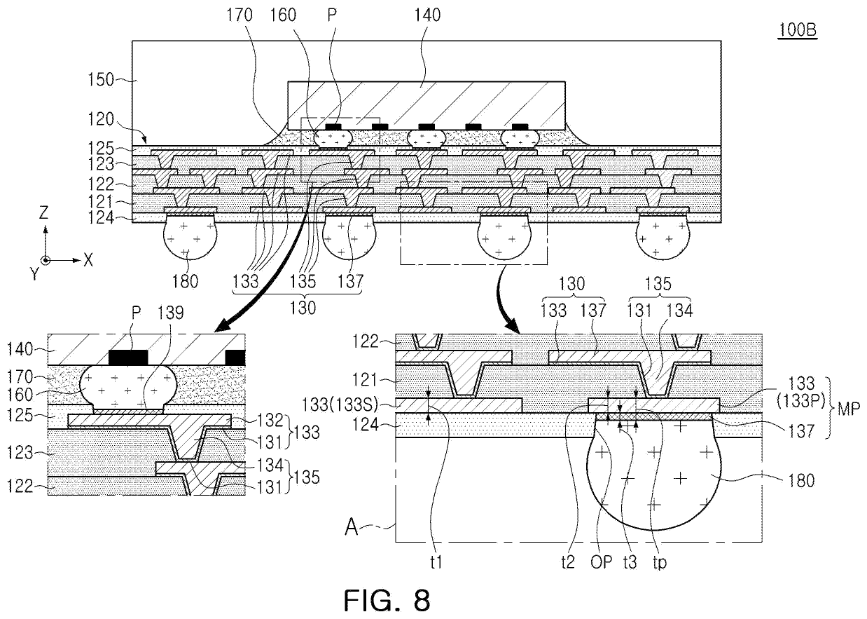

FIGS. 8 to 11 are cross-sectional views of semiconductor packages according to example embodiments, respectively.

Referring to FIG. 8, a semiconductor package 100B may include a substrate structure 120 including the interconnection structure 130 described above with reference to FIG. 1, a semiconductor chip 140, a capping layer 150, and a first connection bump 180. The semiconductor package 100B may further include second connection bumps 160 and an underfill resin 170.

The second connection bump 160 may be disposed between the substrate structure 120 and the semiconductor chip 140 to electrically connect interconnection patterns 133 and a connection pad P of the semiconductor chip 140 to each other. The second connection bumps 160 may have a land, a ball, or a pin shape. The connection bumps 180 may include, for example, tin (Sn) or a tin-containing alloy (for example, Sn—Ag—Cu). The second connection bump 160 may be electrically connected to the interconnection patterns 133 exposed by an opening OP of the second passivation layer 125. The second connection bump 160 may include, for example, a solder ball. In an example embodiment, a metal layer 139 may be disposed between the second connection bump 160 and the interconnection pattern 133 to increase a thickness of a pad structure 133 and 139 connected to the second connection bump 160.

An underfill resin 170 may be disposed to fill a space between the substrate structure 120 and the semiconductor chip 140 and to surround the second connection bump 160. The underfill resin 170 may include an insulating resin such as an epoxy resin. The underfill resin 170 may be a portion of the capping layer 150 formed in a molded underfill (MUF) manner.

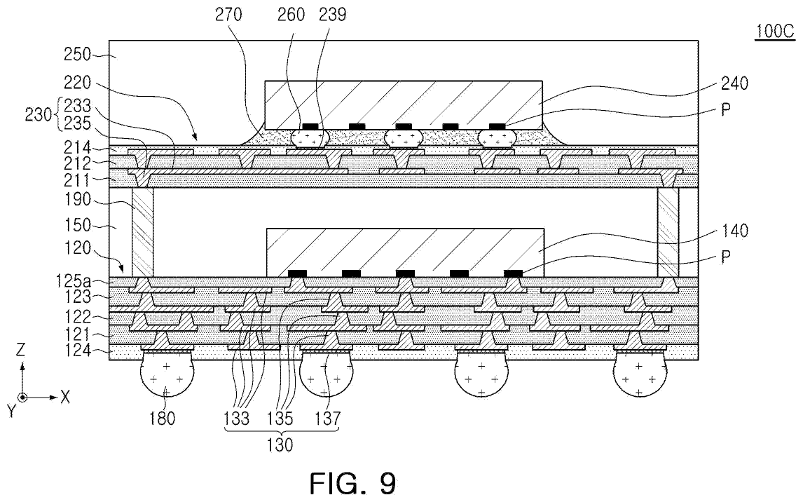

FIG. 9 is a cross-sectional view of a semiconductor package according to example embodiments.

Referring to FIG. 9, a semiconductor package 100C may include a substrate structure 120 including the interconnection structure 130 described above with reference to FIG. 6, a first semiconductor chip 140, a first capping layer 150, and first connection structures 180. The semiconductor package 100C may further include a vertical connection structure 190, a connection structure 220 including an upper interconnection structure 230, a second semiconductor chip 240, a second capping layer 250, a second connection bump 260, and an underfill resin 270.

At least a portion of a side surface of the vertical connection structure 190 may be surrounded by the first capping layer 150, and may penetrate through the first capping layer 150 in a vertical direction Z. The vertical connection structure 190 may be electrically connected to interconnection patterns 133. The vertical connection structure 190 may have a post shape, in which a conductive material penetrates through a portion of the first capping layer 150, or a multilayer substrate shape (for example, a PCB) in which an insulating layer and a conductive layer are sequentially stacked. The vertical connection structure 190 may provide an electrical connection path passing through the first semiconductor chip 140 in the vertical direction (the Z direction). A package-on-package structure may be implemented by the vertical connection structure 190.

The connection structure 220 may be disposed on the first capping layer 150 and the vertical connection structure 190, and may include insulating layers 211 and 212, passivation layer 214, upper interconnection pattern 233, and upper connection vias 235 to correspond to the substrate structure 120. The connection structure 220 may be electrically connected to the second semiconductor chip 240.

The second semiconductor chip 240 may be disposed such that the connection pad P faces the connection structure 220, and may be electrically connected to the upper interconnection patterns 233 through the second connection bump 260 and the metal layer 239. The second semiconductor chip 240 may be the above-described logic chip or memory chip, and may be the same type of chip as the first semiconductor chip 140 or a different type of chip.

The second connection bump 260 may be disposed between the connection structure 220 and the second semiconductor chip 240 to electrically connect the upper interconnection patterns 233 and the connection pad P of the second semiconductor chip 240 to each other. The second connection bumps 260 may have a land, a ball, or a pin shape. The second connection bumps 260 may include, for example, tin (Sn) or a tin-containing alloy (for example, Sn—Ag—Cu). The second connection bump 260 may include, for example, a solder ball. In an example embodiment, a metal layer 239 may be disposed between the second connection bump 260 and the upper interconnection pattern 233 to increase a thickness of a pad structure 233 and 239 connected to the second connection bump 260.

The underfill resin 270 may be disposed to fill a space between the connection structure 220 and the second semiconductor chip 240 and to surround the second connection bump 260. The underfill resin 270 may include an insulating resin such as an epoxy resin. The underfill resin 270 may be a portion of the second capping layer 250 formed in a molded underfill (MUF) manner.

The second capping layer 250 may be disposed to cover the second semiconductor chip 240 and the underfill resin 270 on the connection structure 220. The second capping layer 250 may include an insulating material. Examples of the insulating material may include a thermosetting resin such as an epoxy resin, a thermoplastic resin such as polyimide, or a prepreg including an inorganic filler and/or glass fiber, Ajinomoto Build-up Film (ABF), FR-4, Bismaleimide Triazine (BT), an epoxy molding compound (EMC), and the like.

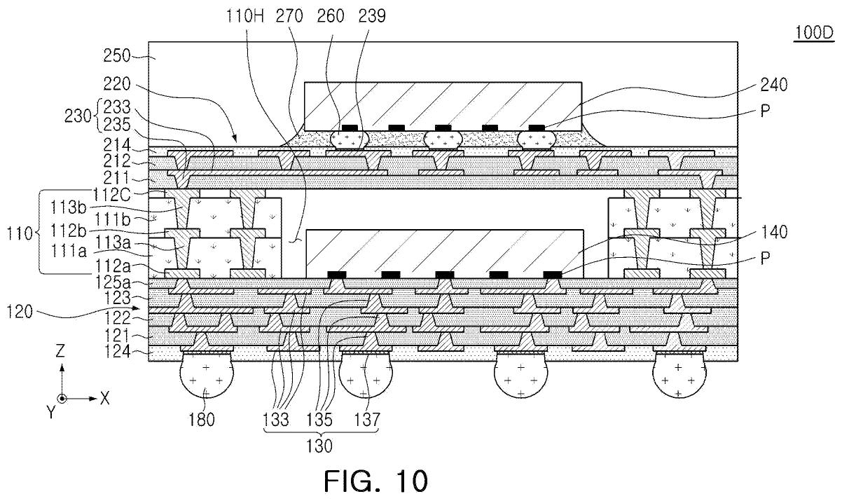

FIG. 10 is a cross-sectional view of a semiconductor package according to example embodiments.

Referring to FIG. 10, a semiconductor package 100D may further include a frame 110 without including the vertical connection structure 190 in the semiconductor package 100C of FIG. 9.

The frame 110 may have a through-hole 110H in which a first semiconductor chip 140 is accommodated. The frame 110 may include core insulating layers 111a and 111b, core interconnection layers 112a, 112b, and 112c, and core vias 113a and 113b. The number and arrangement of the core insulating layers 111a and 111b, the core interconnection layers 112a, 112b, and 112c, and the core vias 113a and 113b, constituting the frame 110, are not limited to those illustrated in the drawing and may vary according to example embodiments.

Each of the core insulating layers 111a and 111b may include an insulating material. Examples of the insulating resin may include a thermosetting resin such as an epoxy resin, a thermoplastic resin such as polyimide, or an insulating material in which these resins are impregnated in a core material such as an inorganic filler and/or glass fibers (glass fiber, glass cloth, glass fabric), for example, prepreg, Ajinomoto Build-up Film (ABF), FR-4, Bismaleimide Triazine (BT), and the like.

The core interconnection layers 112a, 112b, and 112c may serve to redistribute a connection pad P of the first semiconductor chip 140, and may provide a pad pattern for the core vias 113a and 113b for connecting an upper portion and a lower portion of the semiconductor package 100 to each other. The core interconnection layers 112a, 112b, and 112c may include a metallic material such as copper (Cu), aluminum (Al), silver (Ag), tin (Sn), gold (Au), nickel (Ni), lead (Pb), or titanium (Ti), or alloys thereof. The core interconnection layers 112a, 112b, and 112c may perform various functions depending on designs of corresponding layers. For example, the core interconnection layers 112a, 112b, and 112c may include a ground pattern, a power pattern, a signal pattern, and the like. The signal pattern may include various signals, other than a ground pattern and a power pattern related to power, such as a data signal.

The core vias 113a and 113b may electrically connect the core interconnection layers 112a, 112b, and 112c, formed in different layers, to each other. As a result, an electrical path may be formed in the frame 110. The core vias 113a and 113b may include a metallic material. Each of the core vias 113a and 113b may be a filled via completely filled with a metal material, or a conformal via formed along a wall surface of a via hole. Also, each of the core vias 113a and 113b may have a tapered shape, as illustrated. The core vias 113a and 113b may be integrated with at least a portion of the core interconnection layers 112a, 112b, and 112c, but example embodiments are not limited thereto.

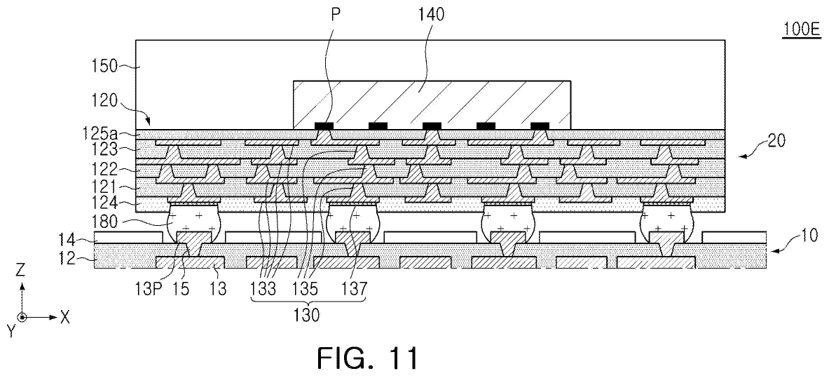

FIG. 11 is a cross-sectional view of a semiconductor package according to example embodiments.

Referring to FIG. 11, a semiconductor package 100E may include a board substrate 10 and a package 20 on the board substrate 10. The package 20 may have a structure corresponding to the semiconductor package described with reference to FIG. 6, but example embodiments are not limited thereto. The package 20 may have a structure corresponding to a semiconductor package according to another embodiment of the present specification.

Two or more packages may be mounted on the board substrate 10. In addition to the two or more packages, various elements, for example, passive elements or active elements, may be further mounted on the board substrate 10. The board substrate 10 may be a printed circuit board (PCB). The board substrate 10 includes, for example, an insulating layer 12, an interconnection layer 13 in the insulating layer 12, a via 15 connected to the interconnection layer 13, and a pad 13P connected to the via 15, and a passivation layer 14. The pad 13P may be exposed from the passivation layer 14 and may be in contact with the connection bump 180. The pad 13P may be electrically connected to the interconnection patterns 133 of the substrate structure 120. In an example embodiment, the pad 13P may have a thickness greater than a thickness of the interconnection patterns 133, and side surfaces of the pad 13P may be inclined.

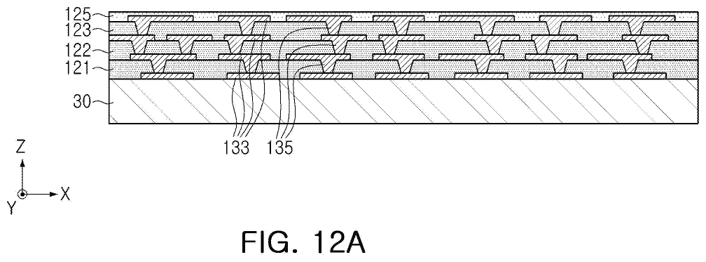

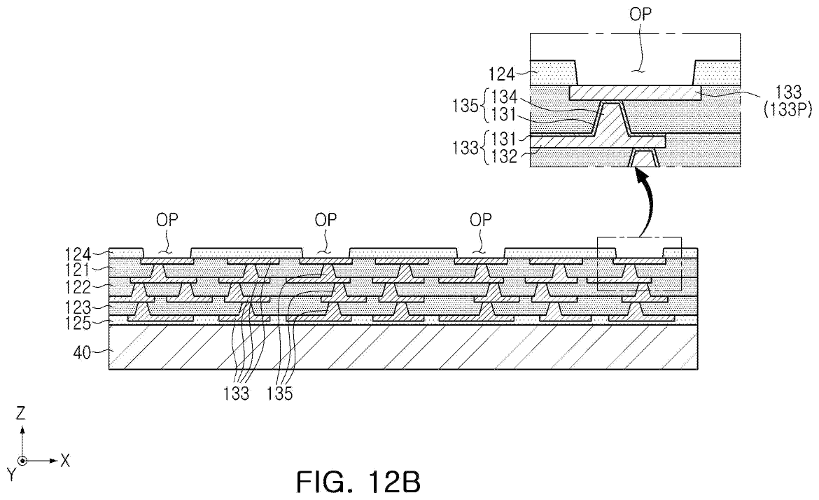

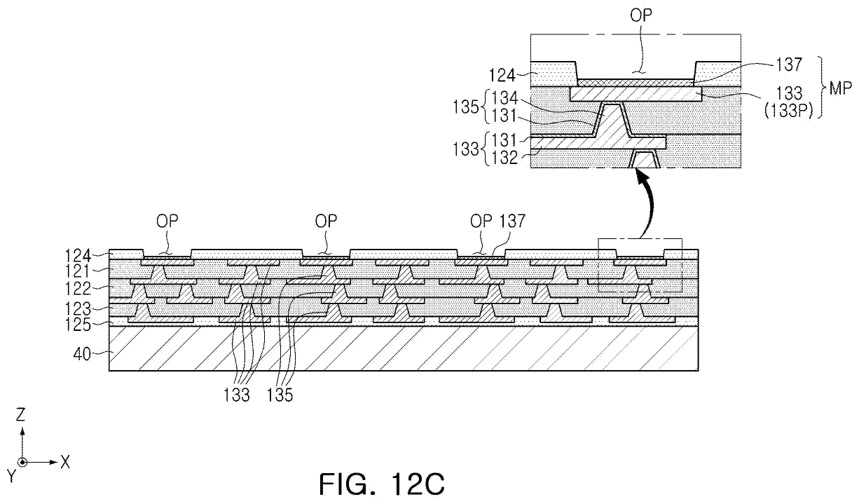

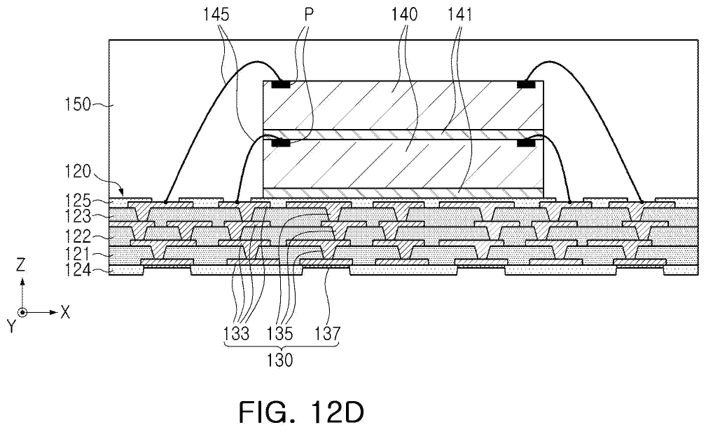

FIGS. 12A to 12D are schematic cross-sectional views illustrating a method of manufacturing the semiconductor package of FIG. 1.

Referring to FIG. 12A, insulating layers 121, 122, and 123, a passivation layer 125, interconnection patterns 133, and connection vias 135 may be formed on a first carrier 30.

The insulating layers 121, 122, and 123 may include a thermosetting resin such as an epoxy resin, a thermoplastic resin such as polyimide, or an insulating material in which these resins are impregnated in a core material such as an inorganic filler and/or glass fibers (glass fiber, glass cloth, glass fabric), for example, prepreg, Ajinomoto Build-up Film (ABF), FR-4, Bismaleimide Triazine (BT), and the like. In an example embodiment, the insulating layers 121, 122, and 123 may include a photosensitive resin such as a photoimageable dielectric (PID) resin.

A portion of the insulating layers 121, 122, and 123 may be patterned to form a via hole, connection vias 135 may be formed to fill the via hole, and interconnection patterns 133 may be formed to be connected to the connection vias 135. When the insulating layers 121, 122, and 123 are formed of a PID as an insulating material, the via hole may be formed using a photolithography process. The via hole may be formed using mechanical drilling or laser drilling. The forming of the connection vias 135 and the interconnection patterns 133 may include forming a seed layer and performing a plating process such as a semiadditive process (SAP) or a modified semiadditive process (MSAP). The forming of the connection vias 135 and the interconnection patterns 133 may include repeatedly performing a photolithography process, an etching process, and a plating process. For example, the interconnection patterns 133 may have a structure in which layers are disposed at four different levels, but example embodiments are not limited thereto. The interconnection patterns 133 may have a structure in which layers are disposed at two different levels. A second passivation layer 125 may be formed to cover a portion of the interconnection patterns 133.

In an example embodiment, connection vias 135 and interconnection patterns 133 may be formed on a semiconductor chip 140 to be directly connected to the connection pad P of the semiconductor chip 140.

Referring to FIG. 12B, the structure formed in FIG. 12A may be reversed to remove the first carrier 30, and may then be attached to the second carrier 40. A first passivation layer 124 may be formed to cover the first insulating layer 121 on the second carrier 40, and openings OP may be formed.

The first passivation layer 124 may include an insulating resin and an inorganic filler, but may not include a glass fiber. For example, the first passivation layer 124 may include ABF, but example embodiments are not limited thereto. The first passivation layer may include a photoimageable dielectric (PID) or an insulating polymer, for example, photosensitive polyimide (PSPI).

A portion of the first passivation layer 124 may be etched such that openings OP are formed to expose the pad pattern 133P, among the interconnection patterns 133. Each of the openings OP may be formed to have a width narrower than a width of the pad pattern 133P. In another example, each of the openings OP may be formed to have a width wider than the width of the pad pattern 133P. A portion of the pad pattern 133P, exposed to the opening OP, may be recessed during the formation of the opening OP.

Referring to FIG. 12C, a plating process may be performed to form a metal layer 137 in the opening OP.

The plating process may be performed on a surface of the pad pattern 133P, exposed to the opening OP, to form the metal layer 137. The plating process may be an electroplating process or an electroless plating process. For example, the plating process may be performed using a method such as a semi-additive process (SAP) or a modified semi-additive process (MSAP), but example embodiments are not limited thereto.

In the opening OP, a surface treatment layer may be further formed to protect the pad structure MP. The surface treatment layer may be formed by, for example, a surface treatment method using an organic solderability preservative (OSP). The organic solder preservative may be an organic solvent having high adhesion to the copper surface, and may serve to prevent oxidation on the surface of the solder ball land during a surface treatment.

Referring to FIG. 12D, the second carrier 40 may be removed, the semiconductor chip 140 may be mounted on the second passivation layer 125, and a bonding wire 145 and a capping layer 150 may be formed.

The semiconductor chip 140 may be mounted on the substrate structure 120 through an adhesive layer 141 of the semiconductor chip 140. The number of the mounted semiconductor chips 140 may vary according to example embodiments, and the connection pads P of each of the semiconductor chip 140 may be electrically connected to the interconnection patterns of the substrate structure 120 through the bonding wire 145.

In an example embodiment, the semiconductor chip 140 may be mounted on the substrate structure 120 through the second connection bump 160 (FIG. 8) such that the connection pad P of the semiconductor chip 140 is in contact with the second connection bump 160, and an underfill resin 170 may be formed, as illustrated in FIG. 8. A metal layer 139 may be further formed on the surface of the interconnection pattern 133 exposed before the second connection bump 160 is formed.

Next, connection bumps 180 may be formed to be connected to the pad structure MP. As a result, the semiconductor package of FIG. 1 may be manufactured.

As described above, a metal layer may be further formed on a pad pattern by a plating process such that a thickness of a pad structure is adjusted to be increased. As a result, a semiconductor package having improved electrical characteristics and reliability may be provided.

While example embodiments have been shown and described above, it will be apparent to those skilled in the art that modifications and variations could be made without departing from the scope of the present inventive concept as defined by the appended claims.

1. A semiconductor package comprising:
a substrate structure comprising a first surface and an opposite second surface;
a semiconductor chip on the first surface; and
a connection bump on the second surface,
wherein the substrate structure comprises:
interconnection patterns at different levels relative to the second surface;
connection vias electrically connecting the interconnection patterns; and
a passivation layer covering a portion of the interconnection patterns and comprising an opening,
wherein the interconnection patterns comprise a first pattern and a second pattern, wherein the first pattern and the second pattern are adjacent to the second surface, and wherein a side surface of the first pattern faces a side surface of the second pattern,
wherein the first pattern is spaced apart from the opening,
wherein the second pattern comprises a pad pattern and a metal layer, wherein the metal layer is between the pad pattern and the connection bump and is in contact with the pad pattern and the connection bump,
wherein the opening of the passivation layer is configured such that the passivation layer does not cover at least a portion of the pad pattern,
wherein the pad pattern and the metal layer each comprise copper (Cu),
wherein the first pattern has a first thickness between an upper surface and a lower surface of the first pattern in a direction perpendicular to the first surface,
wherein the second pattern has a pad thickness between an upper surface and a lower surface of the second pattern in the direction, and
wherein the pad thickness is greater than the first thickness.

2. The semiconductor package of claim 1, wherein the pad pattern has a second thickness between an upper surface and a lower surface of the pad pattern in the direction,
the metal layer has a third thickness between an upper surface and a lower surface of the metal layer in the direction, and
the pad thickness is a sum of the second thickness and the third thickness.

3. The semiconductor package of claim 1, wherein a lower surface of the metal layer is at a level that is lower than a level of the upper surface of the first pattern.

4. The semiconductor package of claim 1, wherein the upper surface of the first pattern and the upper surface of the second pattern are at substantially a same level.

5. The semiconductor package of claim 2, wherein the first thickness of the first pattern is substantially the same as the second thickness of the pad pattern.

6. The semiconductor package of claim 2, wherein the third thickness of the metal layer is smaller than the second thickness of the pad pattern.

7. The semiconductor package of claim 2, wherein the second thickness of the pad pattern is equal to about twice or more of the third thickness of the metal layer.

8. The semiconductor package of claim 2, wherein the second thickness of the pad pattern is about 10 μm or more, and
the third thickness of the metal layer is about 5 μm or more.

9. The semiconductor package of claim 2, wherein a width of the opening is smaller than a width of the pad pattern,
a width of the metal layer is smaller than the width of the pad pattern, and
the metal layer is in contact with a sidewall of the passivation layer defining the opening.

10. The semiconductor package of claim 2, wherein a portion of the pad pattern is recessed, and
the metal layer is in contact with the recessed portion of the pad pattern, wherein the lower surface of the metal layer is at a level lower than a level of the lower surface of the pad pattern.

11. A semiconductor package comprising:
a substrate structure comprising interconnection patterns and connection vias electrically connected to each other, insulating layers covering the interconnection patterns and the connection vias, and a passivation layer having an opening; and
a semiconductor chip on the substrate structure and electrically connected to the substrate structure,
wherein the substrate structure comprises a first surface and an opposite second surface, wherein the semiconductor chip is on the first surface,
wherein the interconnection patterns comprise a pad structure,
wherein the pad structure comprises a pad pattern and a metal layer in contact with a lower surface of the pad pattern,
wherein the pad pattern and the metal layer comprise the same metal,
wherein the pad structure has a pad thickness between an upper surface and a lower surface of the pad structure in a direction perpendicular to the first surface,
wherein one of the interconnection patterns comprises a side surface facing a side surface of the pad structure, wherein the one of the interconnection patterns has a first thickness between an upper surface and a lower surface thereof in the direction, and
wherein the pad thickness is greater than the first thickness.

12. The semiconductor package of claim 11, wherein the same metal is copper (Cu).

13. The semiconductor package of claim 11, further comprising:
a surface treatment layer on a surface of the metal layer and comprising an organic solderability preservative (OSP).

14. The semiconductor package of claim 11, wherein a difference between the pad thickness and the first thickness is about 5 μm or more.

15. The semiconductor package of claim 11, wherein the pad pattern has a second thickness in the direction,
the metal layer has a third thickness in the direction, and
the pad thickness is a sum of the second thickness and the third thickness.

16. The semiconductor package of claim 11, further comprising:
a connection bump in contact with at least one of the pad pattern and the metal layer through the opening,
wherein the connection bump is spaced apart from the interconnection pattern.

17. (canceled)

18. The semiconductor package of claim 15, wherein the third thickness of the metal layer is greater than the second thickness of the pad pattern.

19. (canceled)

20. A semiconductor package comprising:
a substrate structure comprising interconnection patterns and connection vias electrically connected to each other, insulating layers covering the interconnection patterns and the connection vias, a passivation layer having an opening, and a metal layer in at least one region of the opening;
a first semiconductor chip on the substrate structure and electrically connected to the interconnection patterns; and
a first connection bump below the substrate structure and electrically connected to the interconnection patterns,
wherein the interconnection patterns comprise a pad structure,
wherein the pad structure comprises a pad pattern comprising copper (Cu) and a metal layer comprising Cu,
wherein an upper surface of the metal layer is in contact with the pad pattern, a lower surface of the metal layer is in contact with the first connection bump, and a side surface of the metal layer is in contact with the passivation layer at the opening,
a width of the metal layer is smaller than a maximum width of the opening, and
the lower surface of the metal layer is at a level lower than an upper surface of the passivation layer.

21. The semiconductor package of claim 20, wherein the pad structure has a pad thickness between an upper surface and a lower surface of the pad structure in a direction perpendicular to a lower surface of the first semiconductor chip,
one of the interconnection patterns comprises a side surface facing a side surface of the pad structure, wherein the one of the interconnection patterns has a first thickness between an upper surface and a lower surface thereof in the direction, and
the pad thickness is greater than the first thickness.

22. (canceled)

23. The semiconductor package of claim 20, wherein the first semiconductor chip comprises connection pads, and
a portion of the connection vias are directly connected to the connection pads.

24.-26. (canceled)
